(19) United States
(12) Patent Application Publication
(10) Pub. No.: US 2016/0107530 A1
(43) Pub. Date: Apr. 21, 2016

(54) APPARATUS AND METHOD FOR CONTROLLING A CHARGE CURRENT

(71) Applicant: GM GLOBAL TECHNOLOGY OPERATIONS LLC, Detroit, MI (US)

(72) Inventors: Michael C. Roberts, Auburn Hills, MI (US); Calvin Goodman, Auburn Hills, MI (US)

(21) Appl. No.: 14/519,686

(22) Filed: Oct. 21, 2014

(51) Int. Cl. B60L 11/18; H01R 13/66; G01K 7/00; H02J 7/00; G01R 19/00

(52) U.S. Cl. CPC B60L 11/1818; H02J 7/007; G01R 19/0084; G01K 7/00; H01R 13/6683

(57) ABSTRACT

A method and system for controlling a current flow through a charge connector to a charging system includes a charge connector including a plug connectable to a power outlet to receive a current flow, the plug including a temperature sensor to measure an interface temperature at the plug and outlet interface, the charge connector including a coupler connectable to an inlet of the charging system, where one of a control module of the charge connector and a controller of the charging system is operable to control the current flow to an adjusted level determined by one of the interface temperature and a voltage drop at the plug. A communication link may be established by a coupler element connected to an inlet element to transmit signals between the control module and connector. The charge connector may be connectable to a charging system of a plug-in electric vehicle.

### TECHNICAL FIELD

The disclosure generally relates to an apparatus and method for controlling a charge current received from an electrical receptacle outlet by a charge connector, and specifically, controlling the charge current based on a condition of the electrical receptacle outlet detected using the charge connector.

### BACKGROUND

A plug-in electric vehicle (PEV) is a motor vehicle which includes a rechargeable battery, which may also be referred to as a battery pack or fuel cell, which can be charged from an external source of electricity. The electrical energy stored in the rechargeable battery may be used in a PEV to power one or more electric motors that provide tractive torque to propel the vehicle. Plug-in electric vehicles (PEV) include all-electric or battery electric vehicles (BEVs), plug-in hybrid vehicles (PHEVs), and electric vehicle conversions of hybrid electric vehicles and conventional internal combustion engine vehicles.

The battery of a PEV may be charged, for example, using a SAE J1772 AC Level 1 charging level (Level 1), using a standard 120V single phase external power supply provided by a standard 120V electrical power outlet such as a wall outlet electrically connected to a utility power grid or other power source. The battery of a PEV may be charged, for example, using a SAE J1772 AC Level 2 charging level (Level 2), using a 240V split phase external power supply provided by a SAE J1772 AC Level 2 electric vehicle (EV) charging station connected to a utility power grid or other power source. During charging, a charge connector is connected at a first end via a charge connector coupling to an inlet of the charging system of the PEV and is connected at a second end to the Level 1 or Level 2 external power supply. The charge connector may include a plug at the second end for selectively connecting to the external power source via a power outlet of the power supply. The condition of the power outlet and/or the interface between the power outlet and the plug of the charge connector may affect charging conditions when the external power source is connected to the PEV charging system via the charge connector. For example, wear in the contacts of the power outlet may increase the resistance of the connection between the plug connectors (prongs) and the power outlet contacts, causing a rise in temperature at the interface between the plug and power outlet.

### SUMMARY

The charging cycle for charging an energy storage device of a plug-in electric vehicle (PEV) using a charging system of the PEV can be affected by the condition of the power outlet used to connect an external power source to the PEV charging system. For example, wear in the power outlet openings may increase the resistance between the power outlet and the connectors of a charge connector plug inserted into the power outlet openings, causing a rise in temperature at the interface between the plug and power outlet. By controlling the level of current flow through the power outlet, for example, by de-rating the current flow to an adjusted level of current flow, the temperature at the plug-outlet interface can be controlled at or below a temperature threshold. A system for controlling the current flow through a charge connector to a charging system is provided. The charge connector includes a plug selectively connectable to a power supply outlet, the plug including a positive connector to receive a current flow from a power supply via the outlet. The charge connector includes a coupler selectively connectable to an inlet of a charging system to flow current to the charging system via the vehicle inlet. The charge connector includes a first sensor to output a first signal corresponding to a first interface condition at an interface defined by the plug and the outlet when the plug is connected to the outlet. The coupler is operable to transmit the first signal via a communication link between the charge connector and the charging system when the coupler is connected to the inlet.

In one example, the charging system includes a charge controller in communication with the inlet to receive the first signal and determine the first interface condition. The controller is operable to control the current flow through the positive connector at a first adjusted level of current flow based on the first interface condition. The charge connector includes a control module in communication with the first sensor to receive the first signal and determine the interface condition. In one example, the control module is operable to control the current flow through the positive connector at the first adjusted level of current flow based on the interface condition.

The charging system includes a charger connected to the charge controller and configured to charge an energy storage device connectable to the charger. The charge controller is operable to generate a current request signal defining a requested level of current flow requested by the charger, compare the requested level of current flow to the first adjusted level of current flow, and control the current flow to the lesser of the requested level and the first adjusted level of current flow.

In one example, the charge connector includes a second sensor to output a second signal corresponding to a second interface condition at the interface defined by the plug connected to the outlet. The second signal is transmitted to the charge controller via the coupler connected to the inlet, and the charge controller is operable to receive the second signal, determine the second interface condition based on the second signal, and control the current flow to a second adjusted level based on the second interface condition. In a non-limiting example, the first sensor is one of a temperature sensor to measure an interface temperature at the plug-outlet interface and a voltage sensor to measure a sensed voltage at the positive connector of the plug, such that the first interface condition is a respective one of the interface temperature at the interface and a voltage drop between the sensed voltage and an expected voltage defined by the power supply. The second sensor is the other of the temperature sensor and the voltage sensor such that the second interface condition is the respective other of the interface temperature and the voltage drop. The charge controller may be operable to generate a current request signal defining a requested level of current flow requested by the charger, compare the requested level of current flow to the first and second adjusted levels of current flow, and control the current flow to the lesser of the requested level, the first adjusted level, and the second adjusted level. In one example, the coupler includes a coupler communication element and the inlet including an inlet communication element. The coupler communication element is connectable to the inlet communication element to provide the communication link between the charge connector and the charging system when the coupler is connected to the inlet.

A method for controlling a current flow through a charge connector to a charging system is provided. The method includes connecting the charge connector to a power supply outlet, where the charge connector includes a control module, a plug selectively connectable to a power supply outlet and including a positive connector to receive a current flow from a power supply via the outlet, a coupler selectively connectable to an inlet of a charging system to flow current to the charging system via the inlet and to establish a communication link between the charge connector and the charging system, when the coupler is connected to the inlet, and a first sensor to output a first signal corresponding to a first interface condition at an interface defined by the plug and the outlet when the plug is connected to the outlet. The charging system includes a charge controller in communication with the inlet. The method includes sensing the first interface condition at the interface using the first sensor and outputting, via the first sensor, the first signal corresponding to the first interface condition to the coupler. The method further includes transmitting the first signal to at least one of the control module and the charge controller, where the first signal is transmitted to the charge controller via the communication link, and controlling, via at least one of the control module and the charge controller, the current flow through the positive connector at a first adjusted level of current flow based on the first interface condition.

In one example, the charge connector includes a second sensor to output a second signal corresponding to a second interface condition at the interface defined by the plug and the outlet when the plug is connected to the outlet. The method includes sensing the second interface condition at the interface using the second sensor and outputting, via the second sensor, the second signal corresponding to the second interface condition to the coupler. The second signal is transmitted to at least one of the control module and the charge controller, where the second signal is transmitted to the charge controller via the communication link. The method includes controlling, via at least one of the control module and the charge controller, the current flow through the positive connector at a second adjusted level of current flow based on the second interface condition.

The method may include, via at least one of the control module and the charge controller, comparing the first and second adjusted levels of current flow and controlling the current flow through the positive connector at the lesser of the first and second adjusted levels of current flow. In one example, at least one of the control module and the controller sets a diagnostic code when the first interface condition exceeds a first interface condition threshold. In one example, the method includes indicating, via at least one of a display on the charge connector and a user interface of the charging system, one or more of an indication the first interface condition is above the threshold level; and an indication the current flow has been controlled to the first adjusted level.

The above features and advantages and other features and advantages of the present disclosure are readily apparent from the following detailed description of the best modes for carrying out the disclosure when taken in connection with the accompanying drawings.

### BRIEF DESCRIPTION OF THE DRAWINGS

FIG. 1 is a schematic diagram of an example charging system for charging a vehicle including an energy storage device, including a charge connector and a power supply;

FIG. 2A is a schematic end view of a coupler of the charge connector of FIG. 1;

FIG. 2B is a schematic cross-sectional view of section 2B-2B of the coupler of FIG. 2A;

FIG. 3A is a schematic end view of an inlet of the vehicle of FIG. 1;

FIG. 3B is a schematic cross-sectional view of section 3B-3B of the inlet of FIG. 2A;

FIG. 4 is a graph showing different battery charging times for different charging currents;

FIG. 5 is a graph showing a change in temperature over time for different charging currents; and

FIG. 6 is a flow chart describing an example method for controlling a charge current received from an electrical receptacle outlet by a charge connector using the example system of FIG. 1.

### DETAILED DESCRIPTION

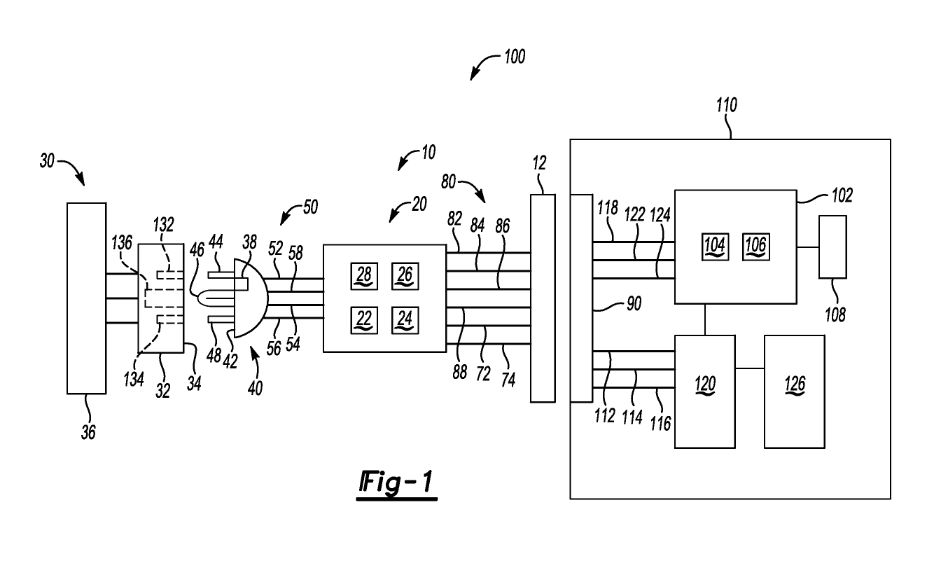

Referring to FIGS. 1-6, wherein like reference numbers correspond to like or similar components throughout the several figures, a system is generally shown at 100 in FIG. 1 for controlling a charge current received from a power outlet 32 by a charge connector 10. The charge connector 10 includes a coupler 12 for connection of the charge connector 10 to an inlet 90 of a charging system 110, and a plug 40 for connection of the charge connector 10 to an outlet 32 of a power supply 30. The figures are not necessarily to scale; some features may be exaggerated or minimized to show details of particular components. As such, specific structural or functional details disclosed herein are illustrative and are not to be interpreted as limiting. Where reference is made to a government or engineering standard or to standard terminology used in a specific geographic region or country, use of such standards and standard terminology is illustrative and is not to be interpreted as limiting. For example, the charging system 110, charge connector 10, coupler 12, plug 40, power supply 30 and power outlet 32 are illustrated and described in the examples provided herein using standard terminology for those components as used in the United States. The use of this terminology, including terms such as 120V power source 36, NEMA plug 40, NEMA outlet 32, SAE J1772 connector, etc., are illustrative, and it would be understood that the invention as described herein and in the accompanying figures and defined in the appended claims may be practiced in various alternative designs and embodiments, including those requiring electrical componentry in non-U.S. regions which would be understood to be equivalent to the componentry described herein by one skilled in the art. For example, the charge connector 10 in the illustrative example in the Figures and described herein includes a SAE J1772 type coupler 12 which would be understood to be equivalent to any PEV coupler 12 such as an IEC type coupler or a VDE-AR-E 2623-2-2 type coupler. The charge connector 10 may also be configured as and/or referred to as an Electric Vehicle Supply Equipment (EVSE) charge connector 10.

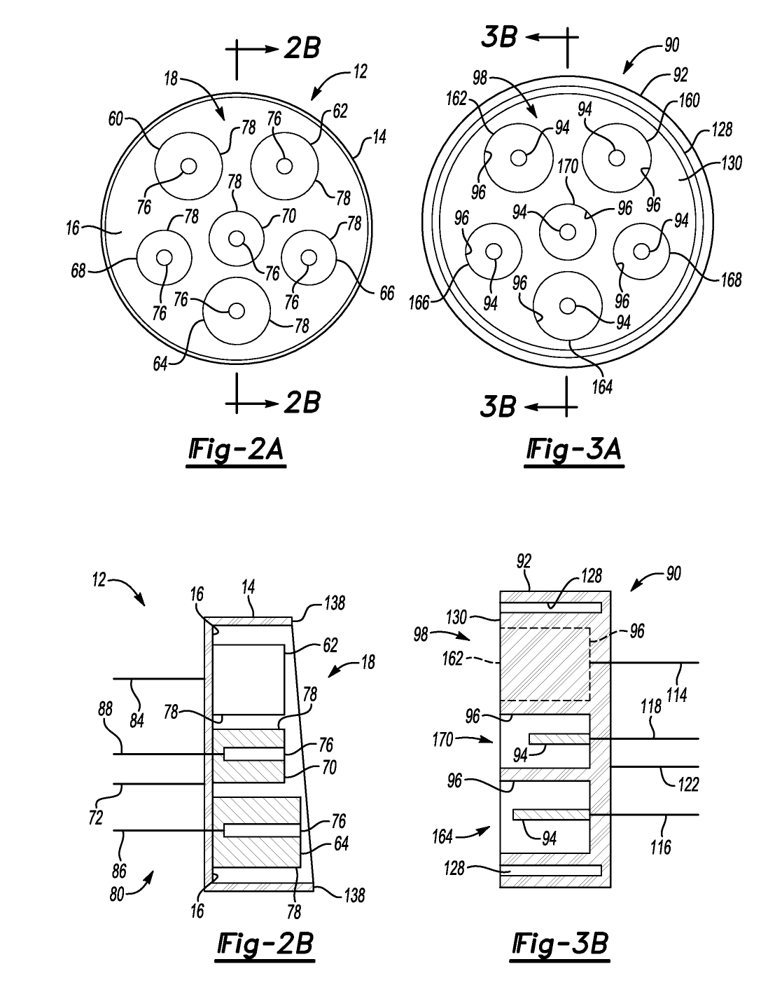

Referring to FIG. 1, the system 100 includes a charge connector generally indicated at 10. The charge connector 10 includes a plug 40 for connecting the charge connector 10 to a power supply generally indicated at 30 and a coupler 12 for connecting the charge connector 10 to an inlet 90 of a charging system 110. The charging system 110, in the example shown, is a charging system 110 of a plug-in electric vehicle (PEV), where the term plug-in electric vehicle (PEV) is descriptive of and includes all-electric or battery electric vehicles (BEVs), plug-in hybrid vehicles (PHEVs), and electric vehicle conversions of hybrid electric vehicles and conventional internal combustion engine vehicles. The charging system 110 includes an inlet 90 for receiving the coupler 12 of the charge connector 10, and further includes a controller 102 including a CPU 104 and a memory 106. The inlet 90, in the non-limiting example shown is configured as a SAE J1772 inlet and is shown in further detail in FIGS. 3A and 3B. The inlet 90 includes an inlet housing 92 including an inlet face 130 and a slot 128, which in the example shown is configured as a radial slot 128 to receive a flange 138 of the coupler 12 housing (see FIG. 2B) when the coupler 12 is connected to the inlet 90, such that the inlet face 130 interfaces with the coupler face 16 (see FIGS. 2A-2B) when the coupler 12 is connected to the inlet 90. The inlet 90 further includes a plurality of inlet connectors 98, each configured to receive a corresponding one of a plurality of coupler connectors 18 when the coupler 12 is connected to the inlet 90. In the example of a J1772 inlet shown in FIGS. 3A and 3B, the plurality of inlet connectors 98 include an AC positive connector 160, an AC neutral connector 162, a ground connector 164, a proximity detection connector 166, and a control pilot connector 168, which are each configured to operate in accordance with SAE specification J1772. The AC positive connector 160, the AC neutral connector 162, and the ground connector 164 are connected to the charger 120, respectively, by a positive wire 112, a neutral wire 114, and a ground wire 116, such that the charger 120 can receive power from the power supply 30 transmitted through the charge connector 10 when the charge connector 10 is connected to the inlet 90 and the power outlet 32. The proximity detection connector 166 is connected to the controller 102 by a proximity detection wire 122, such that the controller 102 can receive a proximity signal transmitted from a control module 20 (see FIG. 1) of the charge connector 10 via a proximity detection connector of the coupler 12 (see FIGS. 2A-2B) when the coupler 12 of the charge connector 10 is fully connected to the inlet 90. The controller 102 is configured to detect the proximity signal transmitted from the control module 20 prior to initiating charging of the battery 126 via the charger 120, to prevent charging of the battery 126 when the coupler 12 is not fully engaged to the inlet 90. The control pilot connector 168 is connected to the controller 102 by a control pilot wire 124, such that the controller 102 can receive a control pilot signal transmitted from the control module 20 of the charge connector 10, where the control pilot signal indicates to the controller 102 the current capacity, e.g., the current rating of the power source 36 to which the charge connector 10 is connected. The control pilot signal is encoded to communicate, for example, a pulse width modulation (PWM) corresponding to a PWM duty cycle or frequency which may indicate ampere capacity available for charging, etc. The control module 20 is configured to generate the control pilot signal when the plug 40 of the charge connector 10 is connected to the power outlet 32 of the power source 36, where the control pilot signal is a pulse width modulated signal defined by the current rating of the power source 36 to which the charge connector 10 is connected.

In one embodiment shown in FIGS. 2A, 2B, 3A and 3B, the plurality of inlet connectors 98 further includes a communication element 170 connected to the controller 102 by a communication wire 118. The communication element 170 is configured to interface with a corresponding communication element 70 of the coupler 12, such that the controller 102 and the control module 20 are in communication with each other, e.g., can transmit data and/or signals between them, when the coupler 12 is connected to the inlet 90, and as further described herein. By way of non-limiting example, the data and/or signals may include information regarding the condition of the power outlet 32, the condition of the plug-outlet interface between the power outlet 32 and the plug 40 which may include temperature data, voltage data including the voltage drop across the electrical connection between the plug 40 and the power outlet 32, diagnostic information including diagnostic codes, and/or commands including commands to de-rate or otherwise adjust the level of current flow and/or control the duty cycle of the output from the control module 20 and/or the charger 120 to limit the current flow provided by the charger 120 to the battery 126. In the example of a SAE J1772 type inlet 90 shown in FIGS. 3A and 3B, each of the inlet connectors 98 may be configured as a barrel type receptacle connector, including a barrel receptacle 96 housing a pin connector 94, where each of the barrel receptacles 96, as shown in FIGS. 3A and 3B, is recessed into the inlet 90 and opens to the inlet face 130. The pin connector 94 may be referred to herein as a pin 94. Each of the plurality of corresponding coupler connectors 18 of an SAE J1772 type coupler 12 shown in FIGS. 2A and 2B may be configured as a barrel type connector, including a barrel 78 terminating in a tip defining a tip opening 76 configured to receive the pin 94 of the corresponding inlet connector 98. Each of the barrels 78, as shown in FIGS. 2A and 2B, protrude from the coupler face 16 such that when the coupler 12 and the inlet 90 are connected, the coupler flange 138 is received by the inlet slot 128 and each of the barrels 78 of the coupler 12 are received into a corresponding barrel receptacle 96 of the inlet 90 such that each pin 94 of the coupler 12 is mated with a tip opening 76 of a corresponding barrel 78 to establish an electrical connection between the corresponding inlet connectors 98 and coupler connectors 18. The communication element 170 of the inlet 90 is configured as a barrel receptacle 96 and pin connector 94, such that a standard J1772 coupler without a communication element 70 can be connected to the inlet 90 shown in FIGS. 3A and 3B. The illustrative example shown is non-limiting, and it would be understood that other electrically mating configurations of the inlet connectors 98 and coupler connectors 18 could be used including combinations of communication elements 70, 170 configured such that the inlet 90 could receive a coupler 12 with or without the communication element 70 present.

The controller 102 is electrically connected to the inlet 90 and to the charger 120 such that the controller 102 is configured to communicate with the control module 20 when the charge connector 10 is connected to the inlet 90 via the coupler 12. In one example, the controller 102 is configured to receive a control pilot signal from the control module 20 via control pilot connectors 68, 168. In another example, the controller 102 communicates with the control module 20 via communication elements 70, 170, as further described herein. The controller 102 and the charger 120 are electrically connected such that the controller 102 can control the charging cycle of the battery 126 being charged by the charger 120. Controlling the charging cycle of the battery 126 may include the controller 102 adjusting the level of current flow to the charger 120 from the power source 36 via the charge connector 10, for example, by de-rating the current draw from the power source 36 via the charge connector 10. The controller 102 may adjust the level of current flow in response to a signal received from the charge connector 10, where the signal indicates a condition of the interface defined by the plug 40 connected to the power outlet 32. The interface defined by the plug 40 connected to the power outlet 32 is the interface of the plug face 42 and the outlet face 34 when the plug 40 is connected to the power outlet 32, and may also be referred to herein as the plug-outlet interface. In one example described in further detail herein, the signal may indicate a temperature sensed and/or measured at the plug-outlet interface, which may be referred to herein as the interface temperature. In another example, the signal may indicate a voltage drop sensed and/or measured between the expected voltage and the voltage sensed at the positive connector 44 of the plug 40.

In another embodiment described in further detail herein, the coupler 12 does not include the communication element 70. In this embodiment, the control module 20 is configured to perform functions which may be performed by the controller 102 in the first embodiment, including, for example, adjusting the level of current flow to the charger 120 from the power source 36 via the charge connector 10 in response to a signal received by the control module 20, where the signal indicates a condition of the interface defined by the plug 40 connected to the power outlet 32, which may be, for example, at least one of the interface temperature of the plug-outlet interface and the voltage drop between the expected voltage and the voltage sensed at the positive connector 44 of the plug 40.

The charging system 110 may further include a user interface 108 which may be configured to display charging information to a user of the system 100, where the user may be a user of a PEV including the charging system 110. The charging information displayed by the user interface 108 may be output by the controller 102 and received for display by the user interface 108. The charging information displayed by the user interface 108 may include one or more of the charging status of the PEV and/or charging system 110, the state of charge of the battery 126, charging conditions including the level of current flow, the duration of the charge cycle, start and stop times for a charging cycle, the estimated time remaining to charge the battery 126 to a predetermined state of charge during a charge cycle, diagnostic codes output by the controller 102 and/or the control module 20, charging condition data such as outlet 32 temperature and/or voltage drop at the outlet 32, etc. The user interface 108 may be configured to display a history of charging events where each charge event corresponds to a charging cycle and may include one or more elements of the charging information.

The controller 102 is electrically connected to a charger 120 and is configured to control the charger 120 during charging of the battery 126 by the charger 120. Controlling the charger 120 includes controlling the level of current draw from the power source 36 and adjusting the flow of current to the battery 126 during the charge cycle. The controller 102 is configured to adjust the flow of current to the battery 126 by the charger 120 to start and stop the charging cycle, e.g., to start and stop charging of the battery 126, for example, based on conditions sensed and inputted to the controller 102 during the charge cycle. The conditions may include, by way of non-limiting example, one or more of the level of current capacity available from the power source 36, the state of charge of the battery 126, the battery temperature, the plug-outlet interface temperature, the voltage drop across the plug-outlet interface, etc.

The charger 120 is operable to charge a battery 126 connected to the charger 120, in response to signals and/or commands received from the controller 102. The battery 126 may also be referred to herein as a rechargeable energy storage device 126. By way of example, the rechargeable energy source, e.g., the battery 126 may be configured as a pack of rechargeable batteries, one or more fuel cells, or other energy storage devices which are capable of storing and being recharged with electrical energy. The electrical energy stored in the rechargeable battery 126 may be used in a PEV to power one or more battery powered mechanisms of the PEV, which may include at least one electric motor (not shown) that provides tractive torque to propel the PEV. The battery 126 is rechargeable with off-board electricity, e.g., chargeable by a power source 36 located external to the charging system 110, by means of connecting the charging system 110 to the power source 36, for example, via the charge connector 10.

The controller 102 includes a computer and/or processor, and includes all software, hardware, memory, algorithms, connections, sensors, etc., necessary to manage and control the charging operation performed by the charging system 110, including controlling the charger 120 to charge the battery 126. For example, the controller 102 may include a central processing unit (CPU) 104 and sufficient memory 106, at least some of which is tangible and non-transitory. The memory 106 may include sufficient read only memory (ROM), random access memory (RAM), electrically-programmable read-only memory (EPROM), flash memory, etc., and any required circuitry including but not limited to a high-speed clock (not shown), analog-to-digital (A/D) circuitry, digital-to-analog (D/A) circuitry, a digital signal processor (DSP), and the necessary input/output (I/O) devices and other signal conditioning and/or buffer circuitry.

As shown in FIG. 1, a power supply 30 can be connected to the charging system 110 via the charge connector 10, by connecting the plug 40 of the charge connector 10 to a power outlet 32 of the power supply 30 and connecting the coupler 12 of the charge connector 10 to the inlet 90 of the charging system 110. The power supply 30 includes a power source 36 electrically connected to the outlet 32. The power source 36 may be connected to the electric power supply 30 grid, for example, such that power is supplied to the power outlet 32. The power supplied to the power outlet 32 may be characterized by an expected current level such that under standard, e.g., normal operating conditions, an expected voltage is generated at the positive connection between the positive connector 44 and the outlet positive socket 132 when the plug 40 is connected to the outlet 32. Under non-standard conditions, e.g., under conditions where the current flow or current level across the plug-outlet interface is affected and/or deteriorated, heat may be generated at the plug-outlet interface in excess of an expected level and/or a voltage drop may occur across the plug-outlet interface, e.g., across the positive connection which is greater than an expected voltage drop. For example, current flow across the plug-outlet interface may be non-standard when one or both of the plug 40 and the outlet 32 are worn, or when the power source 36 is emitting other than the standard level of power, etc. In one example, where Level 1 charging is used, the outlet 32 may be a household power outlet 32 and the power source 36 may be provided from the power grid via the electrical wiring/system 100 of the house including the household power outlet 32. Non-standard conditions in the electrical wiring/system 100 of the house could affect the current level provided to the household outlet 32. Further, the condition of the household outlet 32, including the condition of the outlet sockets 132, 134, 136, could affect the current level provided to the household outlet 32, the voltage drop across the outlet 32, and/or the temperature generated at the outlet 32 when a plug such as the plug 40 of the charge connector 10 is connected to the outlet 32.

The outlet 32 may be configured as a standard outlet 32 compatible with the power source 36. The outlet 32 includes an outlet face 34 including a plurality of sockets 132, 134, 136 opening to the outlet 32 face, where the number and arrangement of plurality of sockets 132, 134, 136 is determined by the type of outlet 32, e.g., by the industry standard to which the outlet 32 complies. For example, where the power source 36 is a 120V power source 36 the outlet 32 is configured as a standard 120V outlet 32, where the power source 36 is a 240V power source the outlet 32 is configured as a standard 240V outlet, and so on. In the non-limiting example shown in FIG. 1, the outlet 32 is configured as a standard 3-prong NEMA 5-15 outlet and the plug 40 is configured as a standard NEMA 5-15 plug, each rated at 125V and 15 amperes. The outlet 32 includes a positive socket 132 for receiving the AC positive connector 44 of the plug 40, a neutral socket 134 for receiving the AC neutral connector 48 of the plug 40, and a ground socket 136 for receiving the ground connector 46 of the plug 40. The positive, neutral and ground sockets 132, 134, 136 of the outlet 32 open to an outlet face 34, such that when the plug 40 is connected to the outlet 32, the plug face 42 is in contact with and/or immediately adjacent to the outlet face 34 of the outlet 32 to define the plug-outlet interface.

The charge connector 10 includes the coupler 12 for connecting to the inlet 90 of the charging system 110, and further includes a control module 20 including a CPU 24 and a memory 22. The coupler 12, in the non-limiting example shown, is configured as a SAE J1772 coupler and is shown in further detail in FIGS. 2A and 2B. The coupler 12 includes a coupler housing 14 including a coupler face 16 and a flange 138, which in the example shown is configured to be received into the radial slot 128 of the inlet 90 (see FIG. 3B) when the coupler 12 is connected to the inlet 90, such that the inlet face 130 interfaces with the coupler face 16 (see FIGS. 2A-2B) when the coupler 12 is connected to the inlet 90. The coupler 12 further includes a plurality of coupler connectors 18, each configured to connect with a corresponding one of a plurality of inlet connectors 98 when the coupler 12 is connected to the inlet 90. In the example of a J1772 coupler 12 shown in FIGS. 2A and 2B, the plurality of coupler connectors 18 include an AC positive connector 60, an AC neutral connector 62, a ground connector 64, a proximity detector connector 66, and a control pilot connector 68, which are each configured to operate in accordance with SAE specification J1772. The AC positive connector 60, the AC neutral connector 62, and the ground connector 64 are connected to the control module 20, respectively, by a positive wire 82, a neutral wire 84, and a ground wire 86, such that the charge connector 10 can transmit power from the power supply 30 through the charge connector 10 via the control module 20 when the charge connector 10 is connected to the inlet 90 and the power outlet 32. The proximity detection connector 66 is connected to the control module 20 by a proximity detector wire 72, such that the control module 20 can transmit a proximity signal to the controller 102 via the proximity detector connector 66 of the coupler 12 when the coupler 12 is fully connected to the inlet 90. The control pilot connector 68 is connected to the control module 20 by a control pilot wire 74, such that the control module 20 can transmit a control pilot signal to the controller 102 via the control pilot connector 68, where the control pilot signal indicates to the controller 102 the current capacity, e.g., the current rating of the power source 36 to which the charge connector 10 is connected. The control module 20 is configured to generate the control pilot signal when the plug 40 of the charge connector 10 is connected to the power outlet 32 of the power source 36, where the control pilot signal is a pulse width modulated (PWM) signal defined by the current rating of the power source 36 to which the charge connector 10 is connected.

In one embodiment shown in FIGS. 2A, 2B, 3A and 3B, the plurality of coupler connectors 18 further includes a communication element 70 connected to the control module 20 by a communication wire 88. The communication element 70 is configured to interface with a corresponding communication element 170 of the inlet 90, such that the controller 102 and the control module 20 are in communication with each other, e.g., can transmit data and/or signals between them, when the coupler 12 is connected to the inlet 90. By way of non-limiting example, the data and/or signals may include information regarding the condition of the power outlet 32, the condition of the plug-outlet interface between the power outlet 32 and the plug 40 which may include temperature data, voltage data including the voltage drop across the electrical connection between the plug 40 and the power outlet 32, diagnostic information including diagnostic codes, and/or commands including commands to de-rate or otherwise adjust the level of current flow and/or control the duty cycle of the output from the control module 20 and/or the charger 120 to limit the current flow provided by the charger 120 to the battery 126. As previously described herein, in the example of a SAE J1772 type coupler 12 shown in FIGS. 2A and 2B, each of the coupler connectors 18 may be configured as a barrel type connector, including a barrel 78 terminating in a tip defining a tip opening 76 configured to receive the pin 94 of a corresponding one of the inlet connectors 98. Each of the barrels 78, as shown in FIGS. 2A and 2B, protrude from the coupler face 16 such that when the coupler 12 and the inlet 90 are connected, the coupler flange 138 is received by the inlet slot 128 and each of the barrels 78 of the coupler 12 are received into a corresponding barrel receptacle 96 of the inlet 90 such that each pin 94 of the coupler 12 is mated with a tip opening 76 of a corresponding barrel 78 to establish an electrical connection between the corresponding inlet connectors 98 and coupler connectors 18.

The control module 20 is electrically connected to the coupler 12 such that the control module 20 is configured to communicate with the controller 102 when the charge connector 10 is connected to the inlet 90 via the coupler 12. In one example, the control module 20 is configured to transmit a control pilot signal to the controller 102 via control pilot connectors 68, 168. In another example, the control module 20 communicates with the controller 102 via communication elements 70, 170, for example to transmit a signal from the control module 20 to the controller 102, where the signal transmitted by the control module 20 indicates a condition of the interface defined by the plug 40 connected to the power outlet 32. The signal may be a temperature signal received from the temperature sensor 38 via a sensor wire 58 connecting the temperature sensor 38 to the control module 20, where the temperature signal indicates the temperature sensed and/or measured at the plug-outlet interface, referred to herein as the interface temperature. In another example, the transmitted signal may indicate a voltage drop sensed and/or measured between the expected voltage and the voltage sensed at the positive connector 44 of the plug 40, where the voltage drop may be sensed, for example, by a voltage sensor 28 included in charge connector 10. In the example shown in FIG. 1, the voltage sensor 28 is housed in the control module 20. The example is non-limiting, such that the voltage sensor 28 may be located elsewhere on the charge connector 10, for example, the voltage sensor 28 may be housed in the plug 40.

In a non-limiting example, the coupler 12 does not include the communication element 70. In this embodiment, the control module 20 is configured to perform functions which may be performed by the controller 102, including, for example, adjusting the level of current flow to the charger 120 from the power source 36 via the charge connector 10 in response to a signal received by the control module 20, where the signal indicates a condition of the interface defined by the plug 40 connected to the power outlet 32, which may be, for example, at least one of the interface temperature of the plug-outlet interface and the voltage drop between the expected voltage and the voltage sensed at the positive connector 44 of the plug 40.

The charge connector 10 may further include a display 26 which may be configured to display charging information to a user of the system 100, where the user may be a user of a PEV including the charging system 110. The charging information displayed by the display 26 may be output by the control module 20 to the display 26. The charging information displayed by the display 26 may include one or more of the charging conditions including the level of current flow, the duration of the charge cycle, start and stop times for a charging cycle, diagnostic codes output by the controller 102 and/or the control module 20, charging condition data such as outlet 32 temperature and/or voltage drop at the outlet 32, etc. The display 26 may be configured to display 26 a history of charging events where each charge event corresponds to a charging cycle and may include one or more elements of the charging information.

The control module 20 includes a computer and/or processor, and includes all software, hardware, memory, algorithms, connections, sensors, etc., necessary to manage and control the charging operation performed by the charge connector 10. For example, the control module 20 may include a central processing unit (CPU 24) and sufficient memory 22, at least some of which is tangible and non-transitory. The memory 22 may include sufficient read only memory (ROM), random access memory (RAM), electrically-programmable read-only memory (EPROM), flash memory, etc., and any required circuitry including but not limited to a high-speed clock (not shown), analog-to-digital (A/D) circuitry, digital-to-analog (D/A) circuitry, a digital signal processor (DSP), and the necessary input/output (I/O) devices and other signal conditioning and/or buffer circuitry.

The plug 40 is electrically connected to the control module 20 by a supply cord generally indicated at 50, where the supply cord 50 is configured to house a plurality of wires 52, 54, 56, 58 connecting the connector 44, 46, 48 and the temperature sensor 38 of the plug 40 to the control module 20. The coupler 12 is electrically connected to the control module 20 by a charging cord 80 configured to house a plurality of wires 72, 74, 82, 84, 86, 88 connecting the coupler connectors 18 of the coupler 12 to the control module 20. The supply cord 50 and the charging cord 80 may each be made of an electrically insulating material configured to enclose the wires and to insulate each of the enclosed wires from each other enclosed wire. The plug 40 includes the temperature sensor 38 positioned, as shown in FIG. 1, proximate and/or immediately adjacent to the plug face 42. In one example, the temperature sensor 38 is positioned on the plug face 42. The temperature sensor 38 is configured to sense the temperature at the plug face 42 such that when the plug 40 is connected to the outlet 32, the temperature sensor 38 senses the interface temperature at the plug-outlet interface and outputs a temperature signal corresponding to the sensed interface temperature to the control module 20. In the example shown, the temperature sensor 38 is connected to the control module 20 via the sensor wire 58.

In use during a charging cycle, for example, during charging of a battery 126 connected to the charging system 110, the plug 40 is connected to the power outlet 32 to receive a current flow from the power supply 30 via the outlet 32. The current flow flows through the positive socket 132 of the outlet 32 and the positive connector 44 of the plug 40 to the control module 20 via the control module 20 to the coupler 12 connected to the inlet 90 of the charging system 110, to flow current to the charging system 110 via the inlet 90, and through the positive connectors 60, 160 to the charger 120, for use by the charger 120 in charging the battery 126. The level of current flow may be adjusted by at least one of the controller 102 and the control module 20 during the charging cycle, where adjusting the level of current flow affects the charging time required to charge the battery 126 to a predetermined state of charge (SOC).

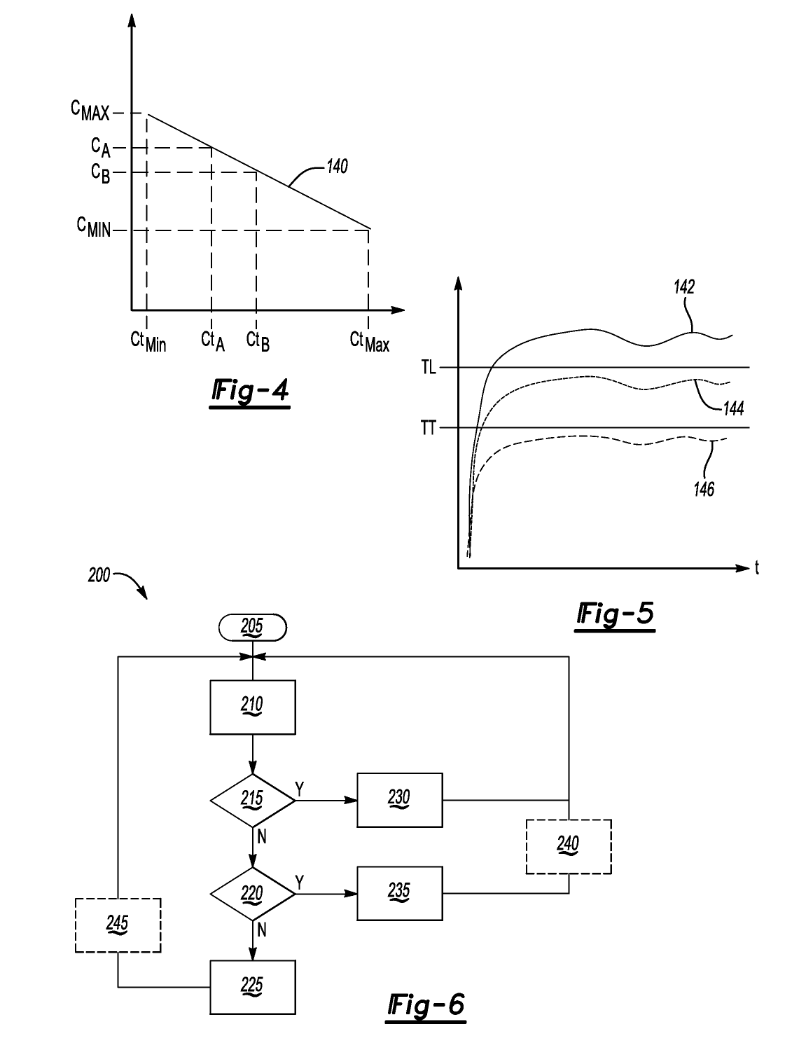

In an illustrative example, the relationship between the level of current flow C and the charging time Ct to attain a predetermined state of charge (SOC) is graphically shown in FIG. 4. As shown in FIG. 4, the charging time Ct decreases as the current flow C increases. For simplicity of illustration, the relationship between current flow C and charging time Ct is shown as a linear relationship represented by the line 140. The example is non-limiting such that it would be understood that the relationship may be linear or non-linear, however such that the minimum charging time Ct_{Min} corresponds to a maximum current flow C_{Max}, and a maximum charging time Ct_{Max} corresponds to a minimum current flow C_{Min}, where Ct_{Min} is less than Ct_{Max} and C_{Min} is less than C_{Min}. In a non-limiting example the maximum current flow may be the highest current flow C_{Max} available from the power source 36 through the outlet 32. In one example, where the outlet 32 is a 120V/15 A outlet, such as a household outlet, the highest current flow expected may be 12 Amperes (Amp). The controller 102 and/or the control module 20 may be configured to de-rate the current flow to a trickle flow, for example, when the battery 126 is charged close to the predetermined and/or maximum SOC, where the trickle flow maintains the SOC of the battery 126 at the predetermined SOC level. In one example, the trickle flow may define the minimum current flow C_{Min}. For example, the minimum current flow C_{Min} is in the range of 3 to 4 Amp when the charge connector 10 is connected to a standard 120V/15 A outlet 32. The controller 102 and/or the control module 20 may be configured to adjust the current flow between the maximum and minimum current flows C_{Max}, C_{Min}, where adjusting the current flow changes the charging time Ct required to attain a predetermined SOC. For example, adjustment of the current flow from C_{Max} to C_{A} increases the charging time from Ct_{Min} to Ct_{A}, and adjustment of the current flow from C_{Min} to C_{B} decreases the charging time from Ct_{Max} to Ct_{B}.

FIG. 5 shows the relationship between the interface temperature T and time t at the plug-outlet interface for various levels of current flow, where the vertical axis of the graph in FIG. 5 represents the interface temperature T at the plug-outlet interface, and the horizontal axis represents time t. As shown in FIG. 5, the temperature T begins increasing at the plug-outlet interface at the time the plug 40 is connected to the outlet 32 and current flows through the plug-outlet interface, and stabilizes at an interface temperature T corresponding to, e.g., defined at least in part by, the current flow C flowing through the plug-outlet interface. In the example shown, each of the interface temperature curves 142, 144, 146 correspond to a different current flow C, where the current flow C corresponding to the interface temperature curve 142 is greater than the current flow C corresponding to the interface temperature curve 144, and the current flow C corresponding to the interface temperature curve 146 is less than the current flow C corresponding to the interface temperature curve 144. The controller 102 and/or the control module 20 may include in its memory a look-up table showing the relationship between the current flow C and the interface temperature T, which may be used by the controller 102 and/or control module 20 to determine adjustments to the current flow C required to control the interface temperature T below a temperature limit T and/or at or below a predetermined threshold temperature TT. In one example, the temperature limit TL corresponds to the plug-outlet interface temperature above which charging is not desirable due to heat generation at the plug-outlet interface. The temperature limit TL may be less than a maximum operating interface temperature, for example, a temperature at which melting of the plug 40 or outlet 32 materials may occur, and may be determined, for example, as a percentage of the maximum operating interface temperature, or by applying a tolerance to the maximum operating interface temperature. The temperature threshold TT corresponds to a predetermined temperature above which the current flow is adjusted by one of the control module 20 and the controller 102 to an adjusted current flow, to lower and/or maintain the interface temperature at the plug-outlet interface to an interface temperature which is less than the temperature limit TL and preferably less than the temperature threshold TT.

Referring again to FIG. 1, during a battery charging cycle, the temperature sensor 38 outputs a temperature signal corresponding to the plug-outlet interface temperature when the plug 40 is connected to the outlet 32. The control module 20 in communication with the temperature sensor 38 receives the temperature signal. In one example, the control module 20 determines the interface temperature and is operable to control the current flow through the positive connector 44 at an adjusted level of current flow based on the interface temperature. The control module 20 determines the adjusted level of current flow by comparing the interface temperature to a temperature limit TL and a temperature threshold TT (see FIG. 5) and decreasing the adjusted level of current flow through the positive connector 44 when the interface temperature exceeds the temperature threshold TT and/or the temperature limit TL. The control module 20 may determine the amount of adjustment to the current flow C required to reduce the interface temperature below the threshold temperature TT, for example, using an algorithm and/or a look-up table providing the relationship between the interface temperature T and the current flow C. The look-up table, in one example, is developed using empirical data, and may be specific for the configuration of the charge connector 10 in combination with the power source 36. The look-up table may be stored, for example, in memory 22 of the control module 20.

The control module 20, in one example, is configured to receive a current request signal from the controller 102. The current request signal may be generated by the controller 102 in response to input received from the charger 120 and/or the battery 126. For example, the charger 120 may signal the controller 102 to reduce current flow through the charger 120 to the battery 126 when the battery 126 SOC is approaching and/or at the predetermined SOC, to reduce the charging rate of the battery 126 to a trickle charge, where in this example the current request signal output from the controller 102 may output a current request signal to request a reduction in the current flow to a trickle flow. In another example, the charging system 110 may be configured to monitor the temperature of the battery 126, and the controller 102 may be configured to reduce the current flow to the battery 126 when the temperature of the battery 126 exceeds a predetermined temperature. In this case, the controller 102 may output a current request signal to request a reduction in the current flow and/or to terminate current flow to the charger 120, for example, until the temperature of the battery 126 is below the predetermined temperature. The control module 20 may be configured to compare the current request signal received from the controller 102, and to adjust the current flow through the charge connector 10 to the lesser of the current flow defined by the current request signal and the adjusted current flow determined by the control module 20 based on a plug-outlet interface temperature.

In one example, during a charging cycle the voltage sensor 28 senses the voltage outgoing from the positive connector 44 to the positive wire 52, and outputs a voltage signal corresponding to outgoing voltage to the control module 20, when the plug 40 is connected to the outlet 32. The control module 20 in communication with the voltage sensor 28 receives the voltage signal. In one example, the control module 20 is operable to determine the voltage drop across the plug-outlet interface using the voltage signal, and is operable to control the current flow through the positive connector at an adjusted level of current flow based on the voltage drop. The control module 20 determines the adjusted level of current flow by comparing the voltage drop to an expected voltage drop, and/or by comparing the outgoing voltage to a voltage threshold, and decreasing the adjusted level of current flow through the positive connector when the voltage drop exceeds the expected voltage drop, and/or when the outgoing voltage is less than the voltage threshold. The control module 20 may determine the amount of adjustment to the current flow C based on the sensed outgoing voltage and/or the voltage drop determined by the control module 20, using an algorithm and/or a look-up table providing the relationship between the sensed outgoing voltage and an expected voltage for the type of energy source to which the charge connector 10 is connected, and/or a look-up table providing the expected voltage drop for the type of power source 36 to which the charge connector 10 is connected. The look-up table, in one example, is developed using empirical data, and may be specific for the configuration of the charge connector 10 in combination with the power source 36, where the expected voltage drop is determined based on acceptable charging conditions at the plug-outlet interface, for example, on charging conditions where the wear and/or relative fit conditions of the connectors are such that the voltage drop is within acceptable limits to continue charging of the battery 126 connected to the power source 36 via the power outlet 32, charge connector 10, and charging system 110. The look-up table and/or algorithm may be stored, for example, in memory 22 of the control module 20. The control module 20 is operable to decrease the adjusted level of current flow incrementally until the interface temperature is equal to or less than the temperature threshold TT, for example, by repeatedly sensing the interface temperature and repeatedly decreasing the adjusted level of current flow until the interface temperature is equal to or less than the temperature threshold TT. In one example, when the interface temperature sensed by the temperature sensor 38 exceeds the temperature limit TL, the control module 20 uses one of an algorithm and the look-up table to determine the adjusted current flow. After adjusting the current flow to the adjusted current flow determined by the algorithm and/or the look-up table, if the interface temperature remains above the temperature threshold TT, the control module 20 may incrementally decrease the current flow until the interface temperature sensed by the temperature sensor 38 is equal to or less than the temperature threshold. In one example, the current flow may be incrementally decreased by a predetermined amount until the interface temperature is maintained below the temperature threshold TT.

As previously described, the controller 102 may output a current request signal to request a reduction in the current flow and/or to terminate current flow to the charger 120. The control module 20 may be configured to receive the current request signal from the controller 102, and to compare the current request signal to an adjusted current flow, where the adjusted current flow has been determined by the control module 20 in response to sensing a voltage drop across the plug-outlet interface, and to adjust the current flow through the charge connector 10 to the lesser of the current flow defined by the current request signal and the adjusted current flow determined by the control module 20 based on at voltage drop.

The control module 20, in one example, is configured to output diagnostic information, which may include one or more diagnostic codes, date and time information when a diagnostic code is generated and/or an operating condition occurs which causes a diagnostic code to be generated. Each of the one or more diagnostic codes may be related to an operating condition of at least one of the outlet 32, the power source 36, the charge connector 10, and the charging system 110, an output from a sensor such as the temperature sensor 38 or voltage sensor 28, an input from the control module 20, etc. For example, a diagnostic code may be output by the control module 20 to indicate the interface temperature at the plug-outlet interface has exceeded a temperature such as the temperature limit TL and/or the temperature threshold TT. For example, a diagnostic code may be output by the control module 20 to indicate the voltage drop across the plug-outlet interface has exceeded a voltage drop threshold, as described further herein. A diagnostic code may be output by the control module 20 to indicate current flow was terminated prior to charging the battery 126 to the predetermined charge level. The examples provided herein are illustrative and not intended to be limiting. The control module 20 may output the diagnostic code with related diagnostic information, such as the date and time the diagnostic code was generated and details of the condition observed, such as the actual interface temperature and/or voltage drop sensed at the time the diagnostic code was generated, etc.

The control module 20 may output the diagnostic code and/or diagnostic information to a display 26 of the charge connector 10 and/or may store the diagnostic code and/or diagnostic information to a memory 22 of the control module 20, such that the diagnostic information including the diagnostic code, the date/time information, the condition details, etc. can be retrieved from the memory 22 at a later time for analysis and/or diagnosis of a charging condition of the vehicle. The control module 20 may output a message via the display 26 to a user of the charge connector 10. The message may include the diagnostic information, and/or may be a message to indicate one or more conditions has occurred during a charging event. Charging event conditions which may be indicated by the message may include, for example, a temperature condition over at least one of the temperature threshold TT and the temperature limit TL, a voltage drop in excess of an expected voltage drop for the power source 36 being used, an adjusted charging time Ct due to adjustment of the current flow during the charging event to an adjusted current flow, cessation of current flow during the charging event, etc. The format and configuration of the message and/or the display 26 may be of any suitable form to convey information to a user of the charge connector 10. For example, the message may be displayed in human readable form and/or characters may be a code output to a display 26, may consist of light signals, sound signals, or a combination of these output by the charge connector 10. The display 26 of the control module 20 is configured to output the diagnostic information and/or the messages in any suitable form to convey the information and messages to a user of the charge connector 10, consistent with the form of the information and messages. For example, the display 26 may consist of one or more of a display screen, a light or combination of lights, an audio output, etc., where the examples provided herein are not intended to be limiting. The control module 20 may output the diagnostic information and/or code to the controller 102, for example, via the communication link established by connection of the communication elements 70, 170.

In another example, the control module 20 outputs the temperature signal and/or an interface temperature determined from the temperature signal to the controller 102 via a communication link established by the coupler 12 connected to the inlet 90, for example, via the communication element 70 connected to the communication element 170. The controller 102 receives the output from the control module 20 and is operable to control the current flow through the positive connector 44 at an adjusted level of current flow based on the interface temperature. The controller 102 determines the adjusted level of current flow by comparing the interface temperature to a temperature limit TL and a temperature threshold TT (see FIG. 5) and decreasing the adjusted level of current flow C through the positive connector 44 when the interface temperature exceeds the temperature threshold TT and/or the temperature limit TL, as described further herein. The controller 102 may determine the amount of adjustment required to reduce the interface temperature below the threshold temperature TT, for example, using an algorithm and/or a look-up table providing the relationship between the interface temperature T and the current flow C. The look-up table, in one example, is developed using empirical data, and may be specific for the configuration of the charge connector 10 in combination with the power source 36. The look-up table and/or algorithm may be stored, for example, in memory 106 of the controller 102. The controller 102 is operable to decrease the adjusted level of current flow C incrementally until the interface temperature is equal to or less than the temperature threshold TT, for example, by repeatedly sensing the interface temperature and repeatedly decreasing the adjusted level of current flow until the interface temperature is equal to or less than the temperature threshold TT. In one example, when the interface temperature sensed by the temperature sensor 38 exceeds the temperature limit TL, the controller 102 uses one of an algorithm and the look-up table to determine the adjusted current flow. After adjusting the current flow to the adjust current flow determined by the algorithm and/or the look-up table, if the interface temperature remains above the temperature threshold TT, the controller 102 may incrementally decrease the current flow until the interface temperature sensed by the temperature sensor 38 is equal to or less than the temperature threshold TT. In one example, the current flow may be incrementally decreased by a predetermined amount until the interface temperature is maintained below the temperature threshold TT.

In the examples described herein, the controller 102 may directly adjust the adjusted level of current flow, or may be configured to send a current request signal to the control module 20 to adjust the current flow, where, for example, the controller 102 and control module 20 are connected via the communication link established by the communication elements 70, 170.

In another example, the control module 20 outputs the voltage signal and/or a voltage drop determined from the voltage signal to the controller 102 via a communication link established by the coupler 12 connected to the inlet 90, for example, via the communication element 70 connected to the communication element 170. The controller 102 receives the output from the controller 102 and is operable to control the current flow through the positive connector 44 at an adjusted level of current flow based on the voltage signal and/or voltage drop. The controller 102 determines the adjusted level of current flow by comparing the voltage drop to an expected voltage drop, and/or by comparing the outgoing voltage to a voltage threshold, and decreasing the adjusted level of current flow through the positive connector 44 when the voltage drop exceeds the expected voltage drop, and/or when the outgoing voltage is less than the voltage threshold. The controller 102 may determine the amount of adjustment to the current flow C based on the sensed outgoing voltage and/or the voltage drop determined by the control module 20, using an algorithm and/or a look-up table providing the relationship between the sensed outgoing voltage and an expected voltage for the type of energy source to which the charge connector 10 is connected, and/or a look-up table providing the expected voltage drop for the type of power source 36 to which the charge connector 10 is connected. The look-up table, in one example, is developed using empirical data, and may be specific for the configuration of the charge connector 10 in combination with the power source 36, where the expected voltage drop is determined based on acceptable charging conditions at the plug-outlet interface, for example, on charging conditions where the wear and/or relative fit conditions of the connectors are such that the voltage drop is within acceptable limits to continue charging of the battery 126 connected to the power source 36 via the power outlet 32, charge connector 10, and charging system 110. The look-up table may be stored, for example, in memory 106 of the controller 102.

The controller 102, in one example, is configured to output diagnostic information, which may include one or more diagnostic codes, date and time information when a diagnostic code is generated and/or an operating condition occurs which causes a diagnostic code to be generated. Each of the one or more diagnostics code may be related to an operating condition of at least one of the outlet 32, the power source 36, the charge connector 10, and the charging system 110, an output from a sensor such as the temperature sensor 38 or voltage sensor 28, an input from the control module 20, etc. For example, a diagnostic code may be output by the controller 102 to indicate the interface temperature at the plug-outlet interface has exceeded a temperature such as the temperature limit TL and/or the temperature threshold TT. For example, a diagnostic code may be output by the controller 102 to indicate the voltage drop across the plug-outlet interface has exceeded a voltage drop threshold, as described further herein. A diagnostic code may be output by the controller 102 to indicate current flow was terminated prior to charging the battery 126 to the predetermined charge level. The examples provided herein are illustrative and not intended to be limiting. The controller 102 may output the diagnostic code with related diagnostic information, such as the date and time the diagnostic code was generated and details of the condition observed, such as the actual interface temperature and/or voltage drop sensed at the time the diagnostic code was generated, etc.

The controller 102 may output the diagnostic code and/or diagnostic information to a user interface 108 of the charging system 110 and/or the PEV including the charging system 110 and/or may store the diagnostic code and/or diagnostic information to a memory 106 of the controller 102 or other memory of the charging system 110 or PEV, such that the diagnostic information including the diagnostic code, the date/time information, the condition details, etc. can be retrieved from the memory 106 and/or the charging system 110 or PEV at a later time for analysis and/or diagnosis of a charging condition of the vehicle, where the charging condition of the vehicle can include the charging condition of the charging system 110 connected to the power source 36 by the charge connector 10. The controller 102 may output a message via the user interface 108 to a user of the charging system 110, charge connector 10 and/or PEV. The message may include the diagnostic information, and/or may be a message to indicate one or more conditions has occurred during a charging event. Charging event conditions which may be indicated by the message may include, for example, a temperature condition over at least one of the temperature threshold TT and the temperature limit TL, a voltage drop in excess of an expected voltage drop for the power source 36 being used, an adjusted charging time Ct due to adjustment of the current flow during the charging event to an adjusted current flow, cessation of current flow during the charging event, etc. The format and configuration of the message and/or the user interface 108 may be of any suitable form to convey information to a user of the charging system 110. For example, the message may be displayed in human readable form and/or characters, may be a code output to a user display 26 in communication with the charging system 110 and/or the controller 102, may consist of light signals, sound signals, or a combination of these output by the controller 102. The user interface 108 is configured to output the diagnostic information and/or the messages in any suitable form to convey the information and messages to a user of the charging system 110, consistent with the form of the information and messages outputted. For example, the user interface 108 may consist of one or more of an interface screen, a light or combination of lights, an audio output, etc., where the examples provided herein are not intended to be limiting. The controller 102 may output the diagnostic information and/or code to a diagnostic tool or other communication interface, for example, via a communication port (not shown) in communication with the controller 102, where the communication port may be a diagnostic communication link of the PEV configured to communicate with a diagnostic tool.

FIG. 6 shows a method generally indicated at 200 for controlling a current flow through a charge connector 10 such as the charge connector 10 shown in FIG. 1, when the charge connector 10 is connected to a power supply 30 and to a charging system, such as the charging system 110 shown in FIG. 1. In a non-limiting example the charging system 110 may be a charging system 110 of a plug-in electric vehicle (PEV) and the charge connector 10 may be an Electric Vehicle Supply Equipment (EVSE) charge connector 10, e.g., the charge connector 10 may be compliant with an EVSE standard such as SAE J1772 or an equivalent thereof applicable to the geographic region and/or to the specific power source 36 to which the charging system 110 is connected by the charge connector 10. The method 200 includes at step 205 connecting the charge connector 10 to a power outlet 32 of a power supply 30 by connecting the plug 40 of the charge connector 10 to the power outlet 32 such that a positive connector 44 of the plug 40 receives a current flow from the power supply 30 via the outlet 32. The charge connector 10 includes a coupler 12 which is selectively connectable to an inlet 90 of the charging system 110 to flow current to the charging system 110 via the inlet 90. The method 200 shown generally in FIG. 6 will be described through illustrative examples such that it would be understood that various configurations of the method 200 may be implemented within the scope of the description provided herein, and it would be understood that the method 200 shown in FIG. 6 is illustrative and not intended to be limiting. As shown in FIG. 6, the method 200 may be implemented such that the steps 210 through 245 may be repeated in a looping manner. The method 200 may be continuously looping or may loop, e.g., be repeated, at a set time interval or at a series of predetermined times, where the manner, frequency and interval in which the method 200 is looped may be determined by the control module 20 and/or the controller 102 and/or predetermined for the charge connector 10 and/or the charging system 110.

In an illustrative example of the method 200, at step 210, the temperature sensor 38 senses the interface temperature and outputs a signal corresponding to the interface temperature to the control module 20 of the charge connector 10. The control module 20 receives the signal and determines the interface temperature from the signal.

At step 215, the control module 20 compares the interface temperature determined at step 210 to a temperature threshold TT. If the interface temperature is less than the temperature threshold TT, for example, as shown by the interface temperature curve 146 of FIG. 5, the method 200 proceeds to step 230. At step 230, the level of current flow from the power source 36 through the charge connector 10 is maintained at the then existing level, and the method 200 returns to step 210, in a looping manner as previously described.

If at step 215 the interface temperature determined at step 210 is greater than the temperature threshold TT, the method 200 continues to step 220 and the interface temperature is compared with a temperature limit TL. If the interface temperature is less than the temperature limit TL, for example, as shown by the interface temperature curve 144 of FIG. 5, the method 200 proceeds to step 235, where the control module 20 reduces the level of current flow incrementally to an adjusted current flow, such that the interface temperature will be decreased proportionally to the reduction in the level of current flow. In a non-limiting example, the increment by which the level of current flow is adjusted by the control module 20 may be a predetermined amount. In other examples, the increment by which the level of current flow is adjusted may be determined by the control module 20 using an algorithm or a look-up table stored in the memory 22 of the control module 20. The method 200 may proceed to an optional step 240, where the control module 20 may perform a diagnostic function, such as setting a diagnostic code and collecting and/or recording related diagnostic information, such as the measured interface temperature, the time the interface temperature was sensed, the time the level of current flow was adjusted, etc. At optional step 240, the control module 20 may perform a communication function, such as outputting a message to the display 26, setting an alert that the level of current flow has been reduced to an adjusted level, for example, to indicate to a user of the charging system 110 and/or the charge connector 10 that charging time Ct may be extended, etc. Following step 235 and optional step 240, the method 200 returns to step 210, in a looping manner as previously described.

If at step 220 the interface temperature is not less than the temperature limit TL, e.g., the interface temperature exceeds the temperature limit TL, for example, as shown by the interface temperature curve 142 of FIG. 5, the method 200 proceeds to step 225, where the control module 20 reduces the level of current flow to an adjusted current flow, such that the interface temperature will be decreased proportionally to the reduction in the level of current flow. The amount by which the level of current flow is decreased at step 225, in a non-limiting example, is determined by the control module 20 using an algorithm or a look-up table stored in the memory 22 of the control module 20. In one example, the control module 20 may be configured to cease current flow through the charge connector 10 when the interface temperature reaches a maximum operating temperature determined by, for example, the configuration of at least one of the charge connector 10, the power outlet 32, and the power source 36. By way of example, the maximum operating temperature is equal to or greater than the temperature limit TL. The method 200 may proceed to an optional step 245, where the control module 20 may perform a diagnostic function, such as setting a diagnostic code and collecting and/or recording related diagnostic information, such as the interface temperature measured, the time the interface temperature was sensed, the time the level of current flow was adjusted, etc. At optional step 240, the control module 20 may perform a communication function, such as outputting a message to the display 26, setting an alert that the level of current flow has been reduced to an adjusted level, for example, to indicate to a user of the charging system 110 and/or the charge connector 10 that charging time Ct may be extended due to the reduction in the level of current flow, or in the event that the current flow was ceased, that the charging system 110 has ceased charging and the battery 126 may not be charged to the desired SOC, etc. Following step 220 and optional step 245, the method 200 returns to step 210, in a looping manner as previously described.

In another illustrative example of the method 200, the charge connector 10 is configured to establish a communication link between the charge connector 10 and the charging system 110 when the coupler 12 is connected to the inlet 90, for example, via the communication elements 70, 170. In this example, at step 210, the temperature sensor 38 senses the interface temperature and outputs a signal corresponding to the interface temperature to the control module 20 of the charge connector 10 and/or to the controller 102 via the communication link. At least one of the control module 20 and the controller 102 receives the signal and determines the interface temperature from the signal and performs steps 215 and 220 above. In one example, the controller 102 determines the amount by which the level of current flow will be adjusted in response to the sensed interface temperature, and decreases the level of current flow through the charge connector 10 to the adjusted level. In another example, the controller 102 determines the amount by which the level of current flow will be adjusted in response to the sensed interface temperature, and generates a current request signal defining the requested level of current flow. The controller 102 outputs the current request signal to the control module 20, and the control module 20 adjusts the level of current flow to the adjusted level of current flow requested by the current request signal. In this example, at least one of the control module 20 and the controller 102 may be configured to perform diagnostic and/or communication functions. For example, the controller 102 may be configured to perform some or all of the diagnostic and/or communication functions described previously for the control module 20, and to generate, record, and or store in memory 106 diagnostic and/or communication information which may be displayed, for example, on the user interface 108 of the charging system 110.

In another example, at least one of the controller 102 and the control module 20 may be configured to compare the adjusted level of current flow determined based on the interface temperature to a level of current flow requested by the charging system 110 based on the charging conditions of the battery 126, and to adjust the level of current flow to the lesser of the adjusted level of current flow determined based on the interface temperature and the level of current flow requested by the charging system 110 based on battery 126 charging conditions. By way of illustrative example, where the charging system 110 is requesting maximum current C_{Max} to minimize charging time Ct of the battery 126, and the method 200 has determined, based on the interface temperature, that a reduction of the level of current flow to current C_{B} is required, at least one of the controller 102 and the control module 20 is configured to compare the requested current C_{Max} to the reduced current C_{B} determined by the interface temperature, and to adjust the level of current flow through the connector to the lesser of these, e.g., to current C_{B}. In another illustrative example, where the charging system 110 is requesting minimum current C_{Min} to sustain the battery 126 charge at the predetermined SOC, and the method 200 has determined, based on the interface temperature, that a reduction of the level of current flow to current C_{A} is required, at least one of the controller 102 and the control module 20 is configured to compare the requested current C_{Min} to the reduced current C_{A} determined by the interface temperature, and to adjust the level of current flow through the connector to the lesser of these, e.g., to current C_{Min}.

In another illustrative example, the method 200 shown in FIG. 6 may be used to sense the voltage level and/or the voltage drop at the positive connector 44, for example using a voltage signal output from the voltage sensor 28 shown in FIG. 1, and received by at least one of the control module 20 and the controller 102. As described in the previous example, the voltage drop can be determined and compared to an expected voltage drop at step 215, and to a voltage drop limit at step 220, to determine whether the level of current flow should be adjusted based on the voltage drop, and the increment and/or amount by which the level of current flow should be adjusted based on the sensed voltage drop. The method 200 may be repeated in a looping manner to continuously or periodically sense the voltage drop across the plug-outlet interface and to adjust the level of current flow in response. By way of example, the control module 20 and/or the controller 102 may use an algorithm or look-up table to determine the adjusted level of current flow based on the sensed voltage drop.

In another example, at least one of the controller 102 and the control module 20 may be configured to compare the adjusted level of current flow determined based on the voltage drop to a level of current flow requested by the charging system 110 based on the charging conditions of the battery 126, and to adjust the level of current flow to the lesser of the adjusted level of current flow determined based on the voltage drop and the level of current flow requested by the charging system 110 based on battery 126 charging conditions. At least one of the controller 102 and the control module 20 may be configured to compare the adjusted level of current flow determined based on the voltage drop, the adjusted level of current flow determined based on the interface temperature, and a current request from the charging system 110 based on the charging conditions of the battery 126, and to adjust the level of current flow through the charge connector 10 to the least of these, e.g., to the lower level of current flow.

The detailed description and the drawings or figures are supportive and descriptive of the invention, but the scope of the invention is defined solely by the claims. While some of the best modes and other embodiments for carrying out the claimed invention have been described in detail, various alternative designs and embodiments exist for practicing the invention defined in the appended claims.

1. A charge connector for controlling a current flow to a charging system, the charge connector comprising:
a plug selectively connectable to a power supply outlet and including a positive connector to receive a current flow from a power supply via the outlet;
a coupler selectively connectable to an inlet of the charging system to flow current to the charging system via the inlet;
wherein the plug includes a temperature sensor to output a temperature signal corresponding to an interface temperature at an interface of the plug and the outlet when the plug is connected to the outlet; and
a control module in communication with the temperature sensor to receive the temperature signal and determine the interface temperature;
wherein the control module is operable to control the current flow through the positive connector at an adjusted level of current flow based on the interface temperature.

2. The charge connector of claim 1, wherein the adjusted level of current flow is determined by the control module comparing the interface temperature to a temperature threshold and decreasing the adjusted level of current flow through the positive connector when the interface temperature exceeds the temperature threshold.

3. The charge connector of claim 2, wherein the control module is operable to decrease the adjusted level of current flow incrementally until the interface temperature is equal to or less than the temperature threshold.

4. The charge connector of claim 2, further comprising:
a connector display;
wherein the control module is operable to indicate on the connector display one or more of detecting an interface temperature above the threshold level and controlling the current flow to an adjusted level.

5. The charge connector of claim 2, wherein the control module is operable to generate a diagnostic code when the interface temperature exceeds the temperature threshold.

6. The charge connector of claim 5, further comprising:
a memory to store the diagnostic code and a time the diagnostic code is generated;
wherein the diagnostic code and the time the diagnostic code was generated is retrievable from the memory.

7. The charge connector of claim 1, further comprising:
wherein the control module is operable to receive a current request signal from the charging system via the coupler when the coupler is connected to the charging system;
wherein the current request signal defines a requested level of current flow requested by the charging system; and
wherein the control module is operable to compare the requested level of current flow to the adjusted level of current flow and to control the current flow to the lesser of the requested level and the adjusted level.

8. The charge connector of claim 1, further comprising:
a voltage sensor for measuring a sensed voltage at the positive connector;
wherein the control module is operable to determine a voltage drop between the sensed voltage and an expected voltage;
wherein the expected voltage is defined by the power supply; and
wherein the control module is operable to control the current flow to an adjusted level based on the voltage drop.

9. A system for controlling a current flow through a charge connector to a charging system, the system comprising:
a charge connector comprising:
a plug selectively connectable to a power supply outlet and including a positive connector to receive a current flow from a power supply via the outlet;
a coupler selectively connectable to an inlet of a charging system to flow current to the charging system via the vehicle inlet;
wherein the charge connector includes a first sensor to output a first signal corresponding to a first interface condition at an interface defined by the plug and the outlet when the plug is connected to the outlet; and
wherein the coupler is operable to transmit the first signal via a communication link between the charge connector and the charging system when the coupler is connected to the inlet;
the charging system further comprising:
a charge controller in communication with the inlet to receive the first signal and determine the first interface condition;
wherein the controller is operable to control the current flow through the positive connector at a first adjusted level of current flow based on the first interface condition.

10. The system of claim 9, further comprising:
wherein the charge connector includes a control module in communication with the first sensor to receive the first signal and determine the interface condition;
wherein the control module is operable to control the current flow through the positive connector at the first adjusted level of current flow based on the interface condition.

11. The system of claim 9, further comprising:
a charger connected to the charge controller and configured to charge an energy storage device connectable to the charger;
wherein the charge controller is operable to:
generate a current request signal defining a requested level of current flow requested by the charger;
compare the requested level of current flow to the first adjusted level of current flow; and
control the current flow to the lesser of the requested level and the first adjusted level of current flow.

12. The system of claim 9, further comprising:
wherein the charge connector includes a second sensor to output a second signal corresponding to a second interface condition at the interface defined by the plug connected to the outlet;
wherein the second signal is transmitted to the charge controller via the coupler connected to the inlet;
wherein the charge controller is operable to receive the second signal, determine the second interface condition based on the second signal; and
wherein the charge controller is operable to control the current flow to a second adjusted level based on the second interface condition.

13. The system of claim 12, wherein:
the first sensor is one of a temperature sensor to measure an interface temperature at the interface and a voltage sensor to measure a sensed voltage at the positive connector such that the first interface condition is a respective one of the interface temperature at the interface and a voltage drop between the sensed voltage and an expected voltage;
the expected voltage is defined by the power supply; and
the second sensor is the other of the temperature sensor and the voltage sensor such that the second interface condition is the respective other of the interface temperature and the voltage drop.

14. The system of claim 12, further comprising:
a charger connected to the charge controller and configured to charge an energy storage device connectable to the charger;
wherein the charge controller is operable to:
generate a current request signal defining a requested level of current flow requested by the charger;
compare the requested level of current flow to the first and second adjusted levels of current flow; and
control the current flow to the lesser of the requested level, the first adjusted level, and the second adjusted level.

15. The system of claim 9, further comprising:
the charging system including a user interface in communication with the charge controller;
wherein the charge controller is operable to indicate on the user interface an occurrence of at least one of:
detecting when the first signal exceeds a first signal threshold, and
controlling the current flow to an adjusted level.

16. The system of claim 9, further comprising:
the charging system including a charger connected to the charge controller;
wherein the charge controller is operable to:
determine a requested level of current flow to charge an energy storage device connectable to the charger;
compare the requested level of current flow to the adjusted level of current flow; and
control the current flow to the lesser of the requested level and the adjusted level.

17. A method for controlling a current flow through a charge connector to a charging system, the method comprising:
connecting the charge connector to a power supply outlet;
the charge connector comprising:
a plug selectively connectable to a power supply outlet and including a positive connector to receive a current flow from a power supply via the outlet;
a coupler selectively connectable to an inlet of a charging system to flow current to the charging system via the inlet and to establish a communication link between the charge connector and the charging system, when the coupler is connected to the inlet;
a first sensor to output a first signal corresponding to a first interface condition at an interface defined by the plug and the outlet when the plug is connected to the outlet;
sensing the first interface condition at the interface using the first sensor;
outputting, via the first sensor, the first signal corresponding to the first interface condition to the coupler;
the charging system further comprising a charge controller in communication with the inlet;
the method further comprising:
transmitting the first signal to the charge controller via the communication link; and
controlling, via the charge controller, the current flow through the positive connector at a first adjusted level of current flow based on the first interface condition.

18. The method of claim 17, further comprising:
the charge connector including a second sensor to output a second signal corresponding to a second interface condition at the interface defined by the plug and the outlet when the plug is connected to the outlet;
sensing the second interface condition at the interface using the second sensor;
outputting, via the second sensor, the second signal corresponding to the second interface condition to the coupler;
transmitting the second signal to the charge controller via the communication link; and
controlling, via the charge controller, the current flow through the positive connector at a second adjusted level of current flow based on the second interface condition.

19. The method of claim 18, further comprising:
comparing, via the charge controller, the first and second adjusted levels of current flow; and
controlling, via the charge controller, the current flow through the positive connector at the lesser of the first and second adjusted levels of current flow.

20. The method of claim 17, further comprising:
indicating, via a user interface of the charging system, one or more of:
an indication the first interface condition is above the threshold level; and
an indication the current flow has been controlled to the first adjusted level.
